(19) United States
(12) Patent Application Publication
(10) Pub. No.: US 2006/0162762 A1
(43) Pub. Date: Jul. 27, 2006

(54) Self-cooled photo-voltaic device and method for intensification of cooling thereof

(76) Inventor: Boris Gilman, Mountain View, CA (US)

Correspondence Address: Boris Gilman, 436 Sierra Vista # 8, Mountain View, CA, 94043, US

(21) Appl. No.: 11/042,632

(22) Filed: Jan. 26, 2005

(51) Int. Cl. H01L 31/042

(52) U.S. Cl. 136/246

(57) ABSTRACT

The invention provides a self-cooled PV device that consists of a PV unit and a radiative cooling unit with specific cooling-enhancing means that covers the solar-energy absorbing side of the PV unit. The aforementioned specific radiation enhancing means may have an electric charge positively induced in the radiative cooling unit for re-arranging the spectrum of the IR radiation towards the spectral range of the ATW. The radiation enhancing means may be comprised of a pre-charged texture formed on the light-receiving surface of the PV unit and coated with an anti-reflection film, a sealed chamber filled with a dipole gas or a mixture of gases, or a combination of the pre-charged texture and the aforementioned gas-filled chamber.

### CROSS-REFERENCES TO RELATED APPLICATIONS

Not Applicable

### BACKGROUND OF THE INVENTION

1. Field of the Invention

The present invention relates to the field of solar-energy conversion, in particular, to self-cooled photo-voltaic devices such as solar cells, solar modules, and solar panels. More specifically, the invention relates to photo-voltaic devices combined with means for intense cooling of such devices by removing heat generated by such devices in the course of their operation. The invention also relates to a method of intensification of cooling of the aforementioned devices.

### BACKGROUND OF THE INVENTION

2. Description of Related Art

A photovoltaic (hereinafter referred to as <<PV>>) cell comprises P-type and N-type semiconductors with different electrical properties, joined together. The joint between these two semiconductors is called the “P-N junction.” Sunlight striking the PV cell is absorbed by the cell. The energy of the absorbed light generates particles with positive or negative charge (holes and electrons), which move about or shift freely in all directions within the cell. The electrons (−) tend to collect in the N-type semiconductor, and the holes (+) in the P-type semiconductor. Therefore, when an external load is connected between the front and back electrodes, electricity flows in the cell.

All known PV devices are heated up by the direct Sun radiation and exchange thermal energy with the ambient. Heating by the Sun results from the energy “unused” in PV conversion of the “PV-active” spectral range (typically 0.3-1.1 μm for the Si-based solar cells) and infra-red (hereinafter referred to as “IR”) absorption of the “PV-inactive” component (wavelength of 1.2-3 μm) with the IR contribution controlled by the solar cell (hereinafter referred to as <<SC>>) design. Ambient (air) temperature is normally either close to or lower than that of the PV device. Under conditions of thermodynamic balance, on an average sunny clear-sky day, a PV device typically operates at a temperature of 40-80° C. with the typical SC temperature being within the range of 50-60° C.

As mentioned by N. B. Mason et al. in IEEE 286th PV. Spec. Conf., p. 1479-1482, it is well known that the temperature coefficient of the maximum output power of a PV device (dPmax/dT) varies (for different SC materials and designs) between −0.4 and −0.5%/° C. in a wide range of temperatures (at least of 20-80° C.). In other words, for the SC or a solar module (hereinafter referred to as <<SM>>) with any nominal Solar Energy Conversion Efficiency (SECE) at 20° C., the corresponding Pₘₐₓ drop at 60° C. will be as high as 16-20% (from the initial 20° C. value), which is significant. And vice versa, for the SC or SM with any given SECE at 60° C., the output power gain at the 40° C. lower temperature is expected to be 16-20%.

The operating temperature of a PV device depends on many factors such as the design (flat-panel, concentrator), materials, mounting technique (roof, open rack), irradiance level and ambient temperature, wind velocity, etc. The temperature coefficient relates more to the PV materials and device parameters. It is clear, however, that operating at elevated temperatures has a significant negative impact on the solar energy production. With the 90% of commercially available solar modules and solar panels represented by the Si-based PV cells and all having high negative temperature efficiency coefficients in actual temperature operating range, a development of effective cooling methods and means for PV devices and systems seem to be critical.

The temperature impact on the PV efficiency is analyzed by Mason in the aforementioned article, as well by A. Hubner et al. in JEEE 26th PV Spec/Conf., pp. 223-226. It is shown that a PV device heating by the unabsorbed IR portion of the Sun radiation (i.e., by “the PV-inactive” component) can be effectively controlled by the proper SC design. The major part of heating, however, is coming from the “PV unused” part of the Sun spectrum and the heat removal mechanism includes both radiation emission and convection (interaction with ambient) with the latter dominating for the typical existing SC and SM operating in the terrestrial environment (so called AM1.0 and AM1.5 atmospheric conditions).

U.S. Pat. No. 4,339,627 issued in 1982 to J. Arnould describes a process for cooling an SC and a combined photovoltaic and photothermal solar device. The device implementing this process comprises a transparent assembly disposed in front of a photovoltaic cell. The transparent assembly, through which flows the cooling fluid leaving a radiator integral with the cell, absorbs the wavelengths greater than 1.1 μm. Thus, the cell of the aforementioned type requires the use of an additional energy source for the supply or circulation of the fluid. Furthermore, heating of the cell is limited and the fluid leaving the radiator is heated by the beam striking the cell.

U.S. Pat. No. 6,407,328 issued in 2002 to J. Kleinwachter discloses a PV device cooled by circulating the liquid medium (i.e., water) between the front side and the radiation source. This cooling technique applies mainly to the limited field of PV systems operating at the concentrating light source (Sun Concentrator). The device described in the aforementioned patent involves the use of many additional features, such as a liquid pump, thermostat, etc., that contributes to the complexity and cost of the PV system, and actually corresponds more to a Thermo PV (TPV) system than to a PV system. While TPV systems are well known and have some specific applications, they have larger dimensions, greater complexity, and higher manufacturing costs, and therefore can not be considered an efficient tools for cooling conventional SC's and SM's.

In <<J. Appl. Phys.>> 52 (6), June 1981, pp. 4205-4220, C. Granqvist and A. Hjortsberg describe the physical principles and experimental results of selective radiative cooling based on the use of selectively emitting SiO films. IR emission takes place through the so called Atmospheric Transparency Windows (ATW). The radiation emitted upward by the surface of the earth travels through the atmosphere where some of it is entirely absorbed by the gases making up the atmosphere and some of it travels through the atmosphere almost unaffected. The wavelength regions of the electromagnetic spectrum most useful, e.g., for measuring surface emission are those regions away from the absorption bands of the atmospheric gases. These transparent “atmospheric window” regions are found in the infrared regions of the spectrum, in particular, in 4-5 μm and 8-13 μm wavelength ranges. While the paper proves the possibility of the significant surface cooling by means of outward IR radiation, it does not relate to the specifics of PV devices. The paper describes only one surface-emitting layer, and does not teach any specific means for enhancing the outward IR radiation by using specific surface profiles or structures.

Several other references, such as, e.g., U.S. Pat. No. 5,405,680 issued in 1995 to D. B. Chang, et al. and U.S. Pat. No. 4,586,350 issued in 1986 to P. H. Berdahl describe various specific coatings for the selective radiative cooling of the underneath surfaces. However, none of the above references either relates specifically to a PV device or describe the possibility of intensification of cooling due to interaction between the surface emitting layers (coatings) and the underlying textured surface of SC or SM.

In <<Solar Energy Materials and Solar Cells>>, V. 40, No. 3, July 1996, pp. 253-259, D. Diatezu, et al. describe the use of an oxynitride film as a promising coating for selective radiation cooling of the underneath surfaces. This particular film is of a special interest for the potential application in PV systems as it may serve as a proper Anti-Reflection Coating (ARC) of SC and SM. The reference however does not include any PV specific information and does not relate to any radiation enhancing mechanism.

Known in the art also are numerous references that describe various types of Si-based SC and SM with the textured light-receiving surface. A comprehensive review of the modem SC's and SM's is presented by M. A. Green (Crystalline and Thin-Film Silicon Solar Cells: State of the Art and Future Potential) in <<Solar Energy”, 74, 2003, pp. 181-192.

Some of the existing SC's with the textured front surface and oxynitride coating used as an ARC have all electrical contacts on the back side, like the one described by M. Gudzinovich and K. Macintosh in the IEEE 29^{th} PV Specialist Conference, pp. 70-72, 2002. Some other references (see, e.g., International Patent Publication WO 03/047005, published on Jun. 5, 2003, inventor A. Munzer) describes methods of fabrication of SC's with textured surface. It is important to note that the textured surface of a modem SC has a surface profile represented by randomly distributed pyramids of a few microns in size with sharp tips. None of the references, however, mentions any relationship between the textured surface and the possibility of radiative cooling of a SC or SM.

Published U.S. Patent Application 2004103680 (Publication date: Jun. 3, 2004; inventor J. Lasich) describes a receiver for a system that generates electrical power from solar radiation. The system includes the receiver and means for concentrating solar radiation onto the receiver. The receiver includes a plurality of PV modules. Each module includes a plurality of PV cells and includes an electrical connection that forms part of the receiver electrical circuit. The receiver includes a coolant circuit for cooling the photovoltaic cells with a coolant. The coolant circuit includes a coolant flow path in each module that is in thermal contact with the PV cells so that in use coolant flowing through the flow path extracts heat from the PV cells and thus cools the cells. A disadvantage of this system is that it requires the use of an additional energy source for driving the cooling liquid. Provision of a cooling-liquid supply system makes the construction more complicated and expensive.

### BRIEF SUMMARY OF THE INVENTION

It is an object of the present invention to provide a method and means for radiative cooling of PV devices such as solar cells and solar modules that are capable of providing an efficient cooling of the surface (preferably textured surface) of the PV device by emitting IR radiation outward. It is another object to provide a PV device that consists of a PV unit and a light-transparent radiative cooling unit that covers the light-receiving surface of the PV unit and has an electric charge positively induced in the radiative cooling unit for re-arranging the spectrum of the IR radiation towards the spectral range of the ATW. It is a further object to provide the aforementioned cooling means that are easy to fabricate and incorporate into a PV device structure, capable of electrical control over the cooling efficiency, compatible with the present SM and SP designs, and cost-effective.

It is still another object to provide a PV device with a quantum-assisted radiative cooling unit operating on the principle of quantum-electrical control of IR radiation intensity. It is a further object to provide a method for intensification of the radiative-cooling rate by charging the textured surface of the PV unit.

The invention provides a self-cooled PV device that consists of a PV unit and a radiative cooling unit with specific radiation enhancing means that covers the solar-energy absorbing side of the PV unit. The aforementioned specific radiation enhancing means may have an electric charge positively induced in the radiative cooling unit for re-arranging the spectrum of the IR radiation towards the spectral range of the ATW and may be comprised of a surface layer (layers) capable of emitting IR radiation within the spectral range that corresponds to the atmospheric transparency windows (ATW) and is typically corresponds mainly to the wavelength between 8 and 13 μm. The aforementioned IR radiation is directed outward from the light-receiving side and removes a thermal energy (heat) from the surface of the PV unit, thus providing efficient cooling of the PV device located underneath the radiative cooling unit. The aforementioned IR emitting layer (layers) may be composed either of selected pre-charged solid films such as, e.g., an oxynitride film or coating that is capable of emitting IR radiation in the aforementioned spectral ranges while providing an efficient ARC for the PV unit, or of a combination of the ARC film with selected gas or a gas mixture, preferably dipole. The aforementioned gas or gas mixture, in a dipole, or a non-dipoler state, is capable of emitting IR radiation in the range of the aforementioned ATW. The surface of the PV unit may be textured, e.g., with a plurality of randomly-distributed pyramide-like micro-projections. Aforementioned IR emitting layers are preferably held in direct contact with the textured and electrically charged surface of the PV unit. The textured surface can be electrically charged by applying electric pulses to the ARC film. It has been unexpectedly found that the use of IR emitting layers in combination with the specifically pre-charged textured surface of a PV unit significantly enhances the outward IR radiation intensity and increases the heat removal rate thus resulting in the improved cooling efficiency of the PV device as a whole.

### BRIEF DESCRIPTION OF THE DRAWINGS

FIG. 1 is a general cross-section of a device of the invention.

FIG. 2 is a cross-sectional view of a device of the invention in accordance with an embodiment, in which cooling enhancing means are made in the form of a sealed chamber filled with a dipole gas or a gas mixture.

FIG. 3 is a cross-sectional view of a device of the invention in accordance with an embodiment, wherein the cooling enhancing means are made in the form of sealed chamber filled with a dipole gas or a gas mixture on the top of the textured surface of a photovoltaic unit.

FIG. 4 is a cross-sectional view of a device of the invention in accordance with an embodiment, wherein the cooling enhancing means are made in the form of an electrically charged texture on the surface of the photovoltaic unit.

FIG. 5 shows absorption/emission spectra of the Earth Atmosphere and spectra of radiative cooling units with and without electrically charged textures.

FIG. 6 is a schematic view for illustrating one of the methods suitable for charging the texture on the surface of the photovoltaic unit.

### DETAILED DESCRIPTION OF THE INVENTION

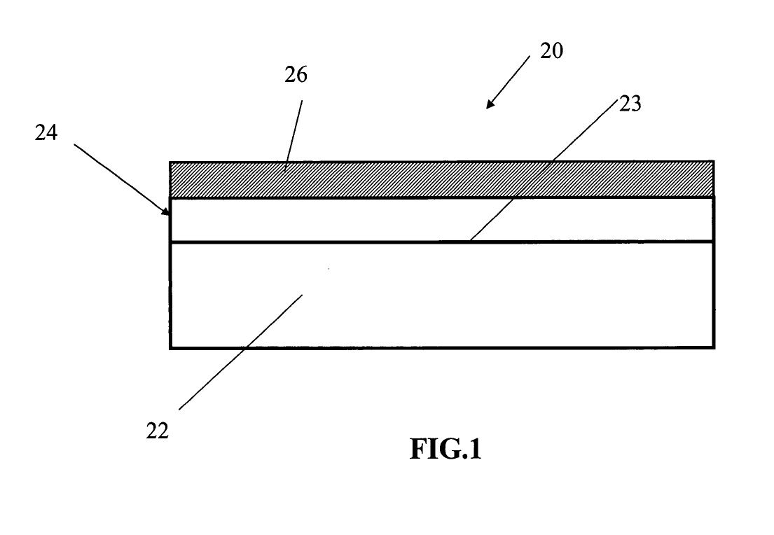

In a simplified general form, a PV device 20 of the invention is shown in FIG. 1, which is a sectional view of the device. It can be seen that the PV device 20 contains a conventional PV unit 22 that may comprise, e.g., a Si-solar cell of the type produced by e.g. BP Solar Co., or described, e.g., by M. A. Green in <<Solar Energy>>, 74, 2003, pp. 181-192. The structure of such a solar cell is well known and is beyond the scope of the present invention. If necessary, the PV unit 22 may be represented by a solar module of the type produced, e.g., by BP Solar Co. It is understood that the above references are given only as examples and do not limit the scope of the application of the invention, provided that a solar-energy generation unit is of a PV type.

The light-receiving side 23 (FIG. 1) of the PV unit 22 supports a cooling-enhancing unit 24 in the form of an IR-emitting layer or layers, which are described in detail later. A characteristic feature of the cooling-enhancing unit 24 is that it is provided with specially designed and made cooling-enhancing means capable of emitting IR radiation in the spectral range of ATW, i.e., 8 to 13 μm. This radiation removes the thermal energy from the PV unit 22 in the outward direction and thus cools the unit 22. Reference numeral 26 designates a transparent protective cover made, e.g., of glass.

Having described the PV device 20 in general, let us consider specific embodiments of the cooling-enhancing unit 24 used in the device 20.

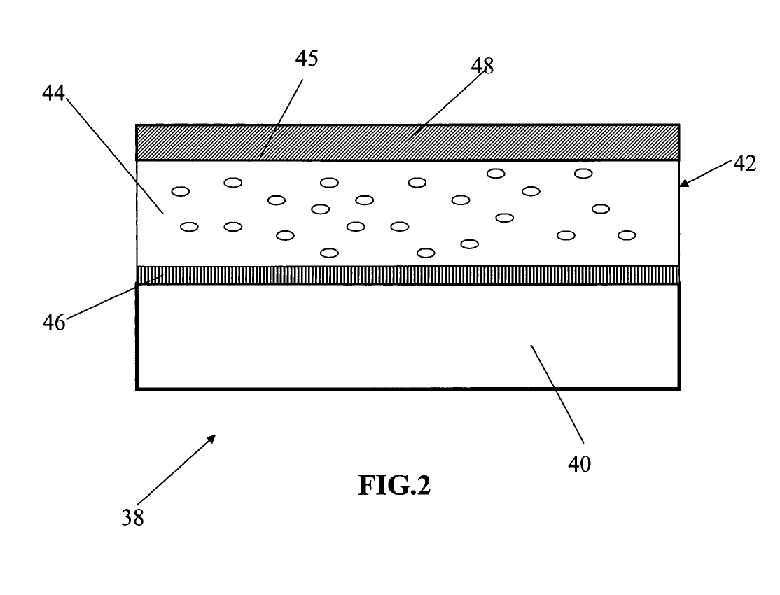

FIG. 2 is a sectional view similar to FIG. 1 that illustrates a PV device 38 that consists of a conventional PV unit 40, e.g., of the same type as the one shown in FIG. 1, and a cooling-enhancing unit 42 that is comprised of a sealed hollow chamber 44 having at least one transparent wall 45, made from a transparent material such as glass, on a light-receiving side. The interior of the chamber 44 is filled with a fluid such as gas or a gas mixture. In this construction, the surface of the PV unit 40 is coated with an anti-reflective coating 46, while the gas or gas mixture is capable of emitting IR radiation in a specific spectral range of ATW. The anti-reflective coating may comprise a conventional anti-reflective film used in known PV devices, e.g., a film of SiO, a SiO₂ film in combination with the film of Si₃N₄, or an oxynitride film of different compositions. The following are examples of gases that can be used individually or in combinations with air: CO, CO₂, CH, SeH₂, etc. Reference numeral 48 designates a transparent protective cover made, e.g., of glass.

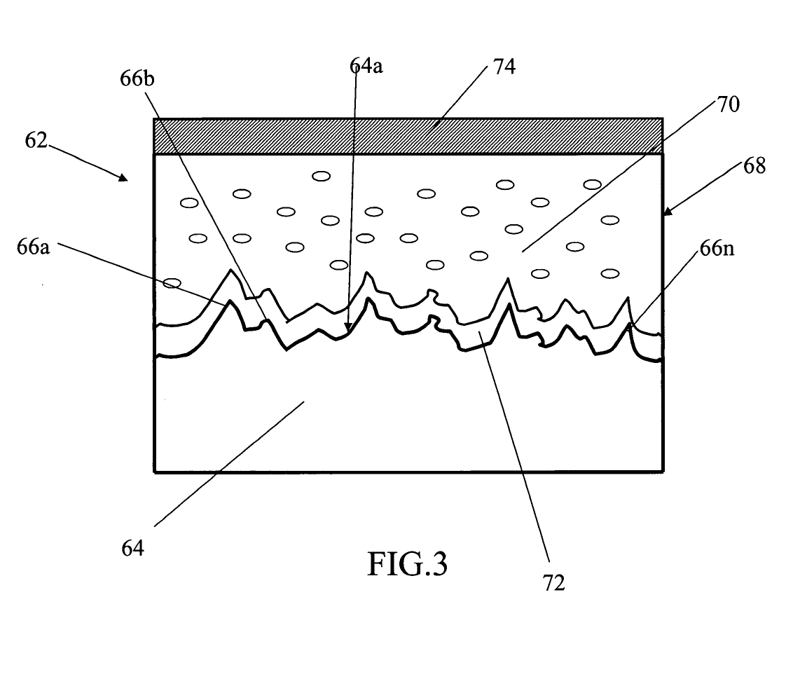

FIG. 3 is a sectional view similar to FIG. 2 that illustrates a PV device 62 that consists of a conventional PV unit 64 with the textured surface 64a formed by randomly arranged microprojections 66a, 66b, . . . 66n and a cooling-enhancing unit 68 that is comprised of a sealed hollow chamber 70 having at least one wall, made from a transparent material such as glass, on a light-receiving side. The interior of the chamber 70 is filled with a fluid such as gas or a gas mixture. In the embodiment of FIG. 3, the textured surface of the PV unit 64 is coated with an anti-reflective coating 72 that conforms to the textured surface by following the texture's profile, while the gas or gas mixture that fills the chamber 70 is capable of emitting IR radiation in a specific spectral range of ATW. The anti-reflective coating 72 may comprise a conventional anti-reflective film of the type described above with reference to FIG. 2. The following are examples of gases that can be used individually or in combinations with air: CO, CO₂, CH, SeH₂, etc. Reference numeral 74 designates a transparent protective cover made, e.g., of glass.

In all embodiments of the PV devices shown in FIGS. 1 to 3, the radiative cooling effect is achieved due to IR radiation emitted by the cooling-enhancement unit deposited or mounted on the light-receiving surface (that may be plain or textured) of the PV device and provided with specially designed and made cooling-enhancing means capable of emitting IR radiation in the spectral range of ATW, i.e., mainly about 8 to 13 μm.

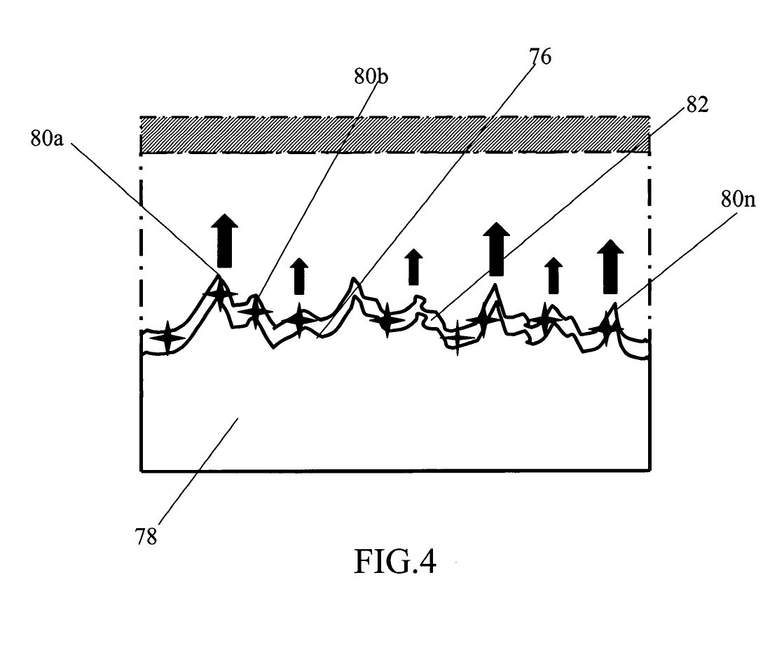

In embodiment shown in FIG. 4, the aforementioned cooling-enhancing means of the PV unit capable of emitting IR radiation in the spectral range of ATW are made in the form of a specifically pre-charged textured surface 76 of a PV unit 78 that has randomly distributed microprojections 80a, 80b, . . . 80n, preferably with sharp tips. Such microprojections can be easily formed, e.g., by etching the surface of the PV unit 78 with an etching solution such as KOH. As can be seen in FIG. 4, similar to the previously described embodiment of FIG. 3, the pre-charged textured surface 76 of the PV unit 78 is also covered with an anti-reflection coating layer 82 that essentially conforms to the coated surface, except for some tips that may project through the coating. Similar to the previous embodiments, the coating layer 82 may be comprised of two or more sublayers such as a thin sub-layer of SiO₂ covered by a thicker layer of Si₃N₄, etc.

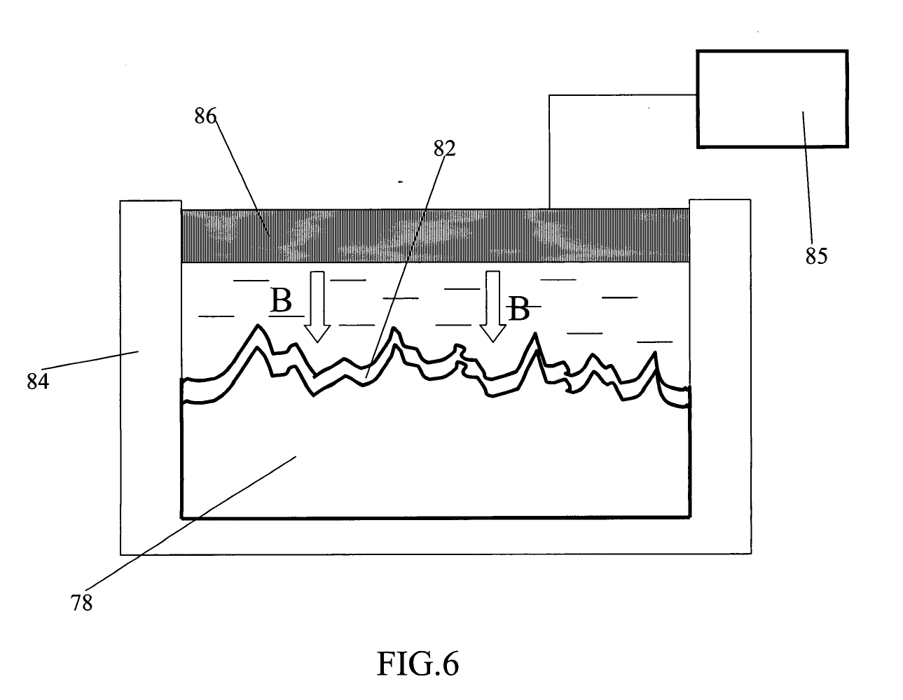

It is shown that the coating layer 82 (or several sub-layers) carries an intentionally induced electrical charge schematically designated in FIG. 4 by “plus” signs. The object of the aforementioned charge is to induce an electric field of the maximum possible magnitude for the specific structure in the vicinity of the microprojection tips. In addition to “plus” signs, the strong electric field developed by this charge in the vicinities of microprojections is also shown in the form of upward arrows. The electric charge is applied to the layer 82 in a manufacturing process which will be described later with reference to FIG. 6.

The PV unit 78 with the pre-charged textured surface 76 of a PV unit 78 may be used as is, or with a gas-filled chamber of the aforementioned type which shown in FIG. 4 by imaginary lines. A combined use of the pre-charged textured surface and a chamber filled with a dipole gas or a gas mixture will further enhance the cooling effect.

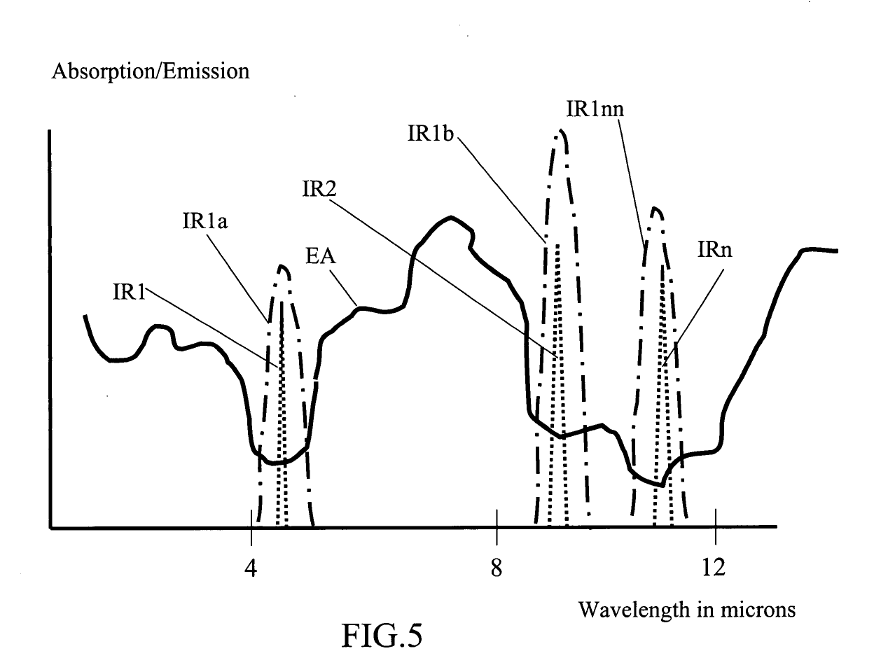

To illustrate a mechanism of the radiative cooling, FIG. 5 shows schematically the radiation absorption/emission spectra of the Earth Atmosphere (EA) (solid line), spectral lines of a non-charged cooling-enhancing unit (broken lines IR1, IR2, . . . IRn), and spectral lines (dash-and-dot lines IR1a, IR2b, . . . IRNn) of a pre-charged cooling-enhancing unit. It can be seen from FIG. 5 that the absorption/emission intensity of IR radiation is the highest in such spectral ranges as, e.g. 8-13 μm that correspond to ATW. It should be noted that in reality the actual spectra of EA and of the cooling-enhancing unit should contain a lot more spectral lines than those shown in FIG. 5.

FIG. 6 is a schematic sectional view that illustrates a charging process for a PV unit surface. Upon completion of application of the coating layer such as, e.g., layer 82 of the PV device 78 (FIG. 4), the unit 78 is placed into a container 84 with the anti-reflection coating layer 82 facing upward. The container is filled with an electrically-conductive liquid, and then the liquid is electrically charged by applying an electrical pulse via a plate electrode 86, e.g., from a pulse generator 84. The electric current that is shown in FIG. 6 by downward arrows B charges the coating layer 82, e.g., with a positive charge having an equivalent density of states of about 10¹¹-10¹³/cm². As an example, the electrical pulse may be of 20-40 V and may have duration from several hundred milliseconds to few seconds. The charged PV unit 78 is removed from the container 84 and is capable of storing the charge during a long period of time. If necessary, with the lapse of time the charging operation can be repeated.

The charging process with the container and with immersion of the PV unit into the container was shown in FIG. 6 only as an example that illustrates the principle. In reality, the charging system may be realized in a more convenient form, e.g., by applying a charging device onto coated PV devices that are moved by a transportation conveyor of a production line.

The electric charge that is present in the coating film, such as, e.g., the coating film 82 of the PV device 78 (FIG. 4), and specifically, at the tips of the microprojections 80a, 80b, . . . 80n, generates a high electric field. According to the Gauss electrostatic law, the magnitude of the aforementioned electric field in any selected point of the coated surfaces can be expressed as follows:
E=−Qₛ/ε=V_{c}/r,
where E is the electric field magnitude, Qₛ is an electric charge density in the anti-reflection film 82, ε is a material permittivity, V_{c}—electrostatic potential developed by the charge Qₛ, and r is a tip radius. Assuming that the electric charge density (expressed through the density of the charged electronic states, as is common in the art) in the anti-reflection (e.g., nitride) film is as high as 10¹¹ to 10¹²/cm² (which is typical in the art) and that the tip radius is within the range of 0.01 to 0.1 μm, one can obtain the electric field in the range of 10⁶ to 10⁷ V/cm.

As shown in FIG. 5 by dot-and-dash lines, the presence of the strong electric field, which in FIG. 4 is shown by upward arrows, will make the spectral lines IR1, IR2, . . . IRn corresponding to a non-charged unit wider by shifting them to the positions of the radiation spectra of aforementioned ATW (including the ones not shown in FIG. 5) that increase the amount of the IR radiation emitted outward from the PV device. This means that a greater amount of heat will be removed from surface of the PV device by outward IR radiation.

We assume that intensification of cooling of a PV device with a pre-charged surface occurs due to the well-known Quantum Stark effect. The aforementioned phenomenon can be especially efficient in the embodiments of FIGS. 3 and 4 where a dipole gas or gas mixture is chosen as an active material for the quantum-assisted radiative cooling unit. For example, in case the selected gas mixture includes both a selectively emitting gas, e.g., SeH₂ and molecules of O₂ and CO₂, the outward IR radiation will be enhanced by both widening the main spectral line of SeH₂ component that lies in the 8-13 μm range and appropriate shifting of the individual spectral lines of other gases such as O₂ and CO₂ in such a way that their respective spectral lines will be positioned in the spectral ranges of the ATW.

The electric field impact can be quantitatively estimated from the Stark equation:
hΔν=αE²/2,
where h is the Plank's constant, ν is light frequency, α is a molecule polarization (relatively high for the dipole gas), and E is the electric field (that depends on the texture charge and tip sharpness). Assuming that E is about 10⁷ V/cm (which is achieved for example at 100V of effective texture potential and tip sharpness of about 0.1 μm), expected line widening Δν will be about 7.5·10¹² Hz, which roughly corresponds to 25% of the light frequency at the “window” wavelength of 9.5 μm. For comparison, the natural line width (i.e., without application of the Quantum Stark effect) is only about 1% of the central frequency. It is understood though that the electric field intensity will go down away from the tips so that an average E in the cooling-enhancing unit is expected to be lower.

Thus, it has been shown that the invention provides a method and means for radiative cooling of PV devices such as solar cells and solar modules that are capable of providing an efficient cooling of the surface (preferably textured surface) of the PV device by emitting IR radiation outward. More specifically, the invention provides a PV device that consists of a PV unit and a light-transparent radiative cooling unit that covers the light-receiving surface of the PV unit and has an electric charge positively induced in the radiative cooling unit for re-arranging the spectrum of the IR radiation towards the spectral range of the ATW The aforementioned cooling-enhancing means are easy to fabricate and incorporate into a PV device structure, capable of electrical control over the cooling efficiency, compatible with the present SM and SP designs, and cost-effective.

The invention has been shown and described with reference to specific embodiments, which should be construed only as examples and do not limit the scope of practical applications of the invention. Therefore any changes and modifications in technological processes, constructions, materials, shapes, and their components are possible, provided these changes and modifications do not depart from the scope of the patent claims. For example, a PV unit can be made of suitable photo-sensitive materials other than Si, such as, e.g., GaAs, InGaAs, amorphous Si, organic materials, nanomaterials, etc. The top portion of the complete PV device located above the radiative cooling unit, such as e.g., top cover, may have various designs and/or materials provided that they are transparent to both PV-active and IR radiation spectral ranges. Depending on the method of texturing, the actual profile of the light-receiving textured surface may vary and can be made, e.g., as inverse pyramids, cones, etc. Although reference is made mostly to dipole gas and dipole gas mixture, as most preferable for the invention, it is not a compulsory condition, and a non-dipole gas or gas mixture can also be used.

What we claim is:

1. A self-cooled photovoltaic device comprising: a photovoltaic unit having a light-receiving surface with an anti-reflection coating through which said photovoltaic unit is capable of receiving a solar radiation; and a cooling-enhancing unit transparent to solar radiation that covers said light-receiving surface, said cooling-enhancing unit having specially designed and made cooling-intensification means capable of emitting IR radiation in the spectral range of atmospheric transparency windows.

2. The self-cooled photovoltaic device of claim 1, wherein said cooling-enhancing unit having specially designed and made cooling-intensification means is selected from the group consisting of 1) a texture formed on said light-receiving surface and coated with an anti-reflection coating that conforms said textured surface and is pre-charged with a charge that is capable of inducing an electric field capable of enhancing said IR radiation; 2) a sealed chamber having at least one side transparent towards said light-receiving surface, said sealed chamber being filled with at least one gas having an IR radiation intensity greater than that of said anti-reflection coating; and 3) a combination of said texture pre-charged with said charge and said sealed chamber filled with said at least one gas.

3. The self-cooled photovoltaic device of claim 2, wherein said photovoltaic unit is selected from the group consisting of a solar cell, solar module, and a solar panel composed of said solar modules.

4. The self-cooled photovoltaic device of claim 1, wherein said anti-reflection coating is selected from the group consisting of a SiO film, a SiO₂ film in combination with a Si₃N₄ film, and an oxynitride film.

5. The self-cooled photovoltaic device of claim 2, wherein said anti-reflection coating is selected from the group consisting of a SiO film, a SiO₂ film in combination with a Si₃N₄, film, and an oxynitride film.

6. The self-cooled photovoltaic device of claim 2, wherein said at least one gas is selected from the group consisting of CO, CO₂, CH, and SeH₂.

7. The self-cooled photovoltaic device of claim 2, wherein said at least on gas is a combination of gases selected from the group consisting of air, CO, CO₂, CH, and SeH₂.

8. The self-cooled photovoltaic device of claim 2, wherein said texture is charged with an electrical charge.

9. The self-cooled photovoltaic device of claim 8, wherein said texture is formed by randomly distributed microprojections having substantially sharp tips and wherein said electric field is concentrated essentially in the vicinity of said tips.

10. The self-cooled photovoltaic device of claim 4, wherein said texture is charged with an electrical charge.

11. The self-cooled photovoltaic device of claim 10, wherein said texture is formed by randomly distributed microprojections having substantially sharp tips and wherein said electric field is concentrated essentially in the vicinity of said tips.

12. The self-cooled photovoltaic device of claim 5, wherein said texture is charged with an electrical charge.

13. The self-cooled photovoltaic device of claim 12, wherein said texture is formed by randomly distributed microprojections having substantially sharp tips and wherein said electric field is concentrated essentially in the vicinity of said tips.

14. The self-cooled photovoltaic device of claim 6, wherein said texture is charged with an electrical charge.

15. The self-cooled photovoltaic device of claim 14, wherein said texture is formed by randomly distributed microprojections having substantially sharp tips and wherein said electric field is concentrated essentially in the vicinity of said tips.

16. A method for intensification of cooling of a photovoltaic device comprising a photovoltaic unit having a light-receiving surface with an anti-reflection coating through which said photovoltaic unit is capable of receiving a solar radiation; and a cooling-enhancing unit transparent to solar radiation that covers said light-receiving surface, said cooling-enhancing unit having specially designed and made cooling-intensification means capable of emitting IR radiation in the spectral range of ATW, said method comprising the steps of:
forming a texture on said light-receiving surface; and
charging said texture with an electric charge for generating an electric field that widens and shifts radiation spectra of said IR radiation of said cooling-intensification means towards said spectral range of ATW.

17. The method of claim 16, further comprising the step of forming said texture in the form of randomly distributed microprojections with tips and concentrating said electric field essentially in the vicinity of said tips.
